(19) United States
(12) Patent Application Publication
(10) Pub. No.: US 2010/0194202 A1
(43) Pub. Date: Aug. 5, 2010

(54) System and method for integrated solar power generator with micro inverters

(76) Inventor: David Sun, San Diego, CA (US)

Correspondence Address: Jian Chen, 1200 Pine St, Palo Alto, CA, 94301, US

(21) Appl. No.: 12/322,390

(22) Filed: Jan. 31, 2009

(51) Int. Cl. H05K 13/04; H01L 31/042; H02J 1/06

(52) U.S. Cl. 307/82; 136/251; 29/729

(57) ABSTRACT

Apparatuses, methods, and systems directed to an integrated solar electric power generation system. Some embodiments of the present invention comprise one or more integrated photovoltaic solar panels each incorporating one or more solar modules which convert Sun light energy to DC electric power and one or more micro inverters which convert DC power received from the solar modules to produce AC power. The integrated solar panel provides connections that can be easily connected to additional integrated photovoltaic solar panels. Other embodiments of the present invention can be used to connect multiple integrated solar panels through an AC bus to which an AC load center is connected and provides power to the application electrical power loads and/or a utility grid. Yet other embodiments of the present invention comprise one or more integrated solar panels that are connected through one or more local AC buses. The local AC buses are then connected through a main bus to an AC load center that provides power to the application electrical power loads and/or a utility grid.

### TECHNICAL FIELD

This invention relates to an integrated solar electric power generation system.

### BACKGROUND

Compared with most other energy sources, solar energy is cleaner and more available. The supply of solar energy from its source, the Sun, is the most abundant. Solar light energy can be converted to electricity to power households, buildings, factories, appliances, and other places or devices where electrical power is needed. Although solar powered applications in space have been in existence for decades, terrestrial residential or industrial use of solar electric power generation systems to power a household or a building is still relatively limited. High cost of solar electric power systems and complexity in the installation and connection of such systems to existing electrical systems and application electrical power loads present challenges to potential customers of solar electric power systems.

Existing solar electric power systems for residential or industrial use carry a high entry cost. For example, the cost of a 2 kilowatt (KW) photovoltaic (PV) system is estimated at $13,000 to $20,000 by the California Energy Commission. A 2 KW system with 16% efficient PV modules requires a relatively large 160 square feet of open space for installation. In addition, such systems typically require the installation of one or more solar panels on top of a roof of a building structure, in an open space such as the front yard or the backyard of a building, or on the balcony, or the roof, of an apartment building. Qualified electricians are needed to modify the electrical service panel of a house or building so that the generated power can be used to supply household power consumption and/or to sell excess power back to the electric utility company.

The relatively high entry cost is a major barrier for many potential consumers of solar electric power systems. However, with rapidly increasing solar panel manufacturing capacity, the cost of solar electric power system is quickly decreasing. The efficiency of solar PV modules to convert light energy into electrical power is also improving. Solar power systems may provide primary or supplementary power to residential, building, or an enterprise level power grid. Some solar systems are being installed at power plants to supply electric power to the public utility power grid.

However, installing solar panels at residential homes, at business locations, or at power plants presents installation challenges. Modular solar panels that provide AC power and can be easily connected with one another may be desirable. The requirement to have qualified electricians to modify the electrical service panels also increases the cost for prospective customers of solar electric power systems.

In this and other contexts, a key factor that limits the adoption of solar electric power systems is the cost of solar system components with associated complexity in system connection, installation and supply of electrical power to the electrical system of a household, a utility grid, or a building. For a typical residential home or an office building, it is common to have limited open space for solar electric power system installation. To ensure wide adoption, a solar electric power system may need to be easily connected and installed. The system may also need to be easily connected to the electrical system of a household or building to supply electrical power, ideally without any modification to the existing electrical service panels.

### SUMMARY

The present invention provides apparatuses, methods, and systems directed to an integrated solar electric power generation system. Some embodiments of the present invention allow an integrated photovoltaic solar panel comprising one or more solar modules each capable of converting solar energy to DC electric power. The integrated solar panel further comprises one or more micro inverters which receive the DC power and convert it to AC power. The integrated solar panel provides connections that can be easily connected to other integrated solar panels. The output of the integrated solar panel may be connected to a wall outlet to supply electrical power. Other embodiments of the present invention can be used to connect multiple solar panels through an AC bus to which an AC load center is connected and provides power to application electrical power loads and/or a utility grid. Yet other embodiments of the present invention comprise one or more integrated solar panels that are connected through one or more local AC buses. The local AC buses are then connected through a main bus to an AC load center that provides power to application electrical power loads and/or a utility grid.

In one embodiment of the present invention, the apparatuses and methods are directed to an integrated solar power generation system which comprises one or more solar modules and one or more micro inverters. The solar modules comprise one or more solar cells that convert solar light energy to DC electrical power. The micro inverters monitor the converted electrical power and convert the DC power to AC power. In some embodiments, an integrated solar panel may comprise one or more sub-panels each comprising one or more solar modules and one or more micro inverters that produce AC power. The solar modules may be connected in parallel or in series to the micro inverter. One or more sub-panels may be easily connected through electrical wires.

In other embodiments of the present invention, the apparatuses, methods, and systems involve integrated solar electric power systems that may be connected to an indoor or outdoor wall outlet to supply the generated electrical power without modifying the electrical service panel. In some other embodiments of the present invention, one or more solar panels may be connected by an AC bus which is connected to an AC load center to provide power to application electrical power loads and/or a utility grid. In other embodiments, one or more solar panels may be connected by one or more local buses and the local buses are connected to a main AC bus which is connected to an AC load center to provide power to application electrical power loads and/or a utility grid.

The following detailed description together with the accompanying drawings will provide a better understanding of the nature and advantages of various embodiments of the present invention.

### DESCRIPTION OF THE DRAWINGS

FIG. 1 is a diagram showing an example integrated solar panel, which panel may be used with an embodiment of the present invention.

FIG. 2 is a diagram showing another example integrated solar panel, which panel may be used with an embodiment of the present invention.

FIG. 3 is a diagram showing yet another example integrated solar panel, which panel may be used with an embodiment of the present invention.

FIG. 4 is a diagram showing an example integrated solar power generation system, which system may be used with an embodiment of the present invention.

FIG. 5 is a diagram showing another example integrated solar power generation system, which system may be used with an embodiment of the present invention.

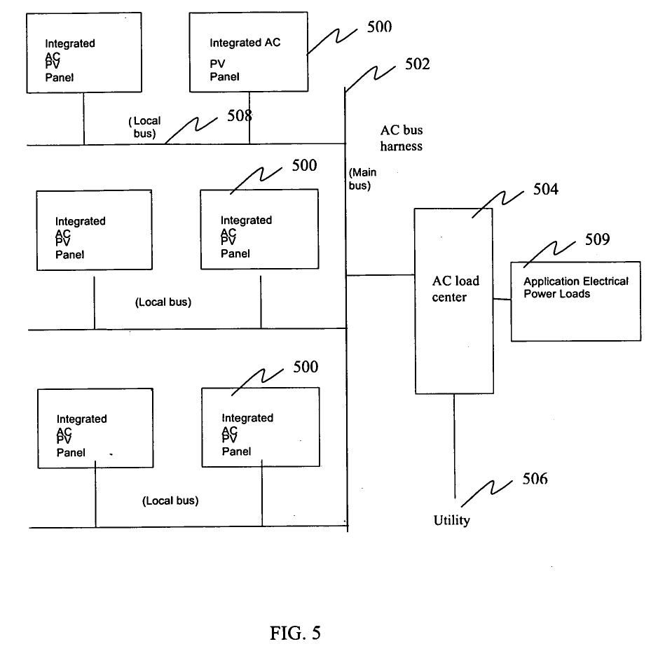

FIG. 6 is a diagram showing an example micro inverter, which inverter may be used with an embodiment of the present invention.

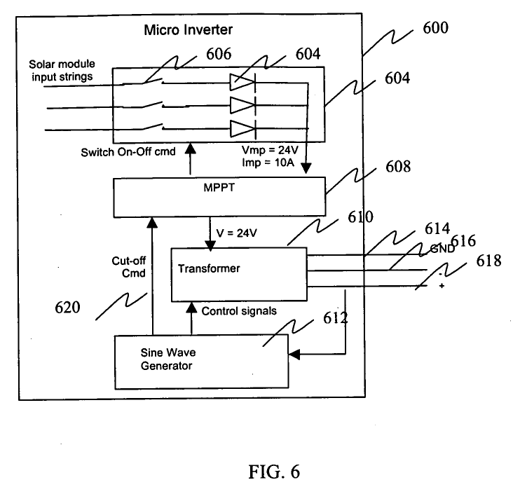

### DESCRIPTION OF EXAMPLE EMBODIMENT(S)

The following example embodiments and their aspects are described and illustrated in conjunction with apparatuses, methods, and systems which are meant to be illustrative examples, not limiting in scope.

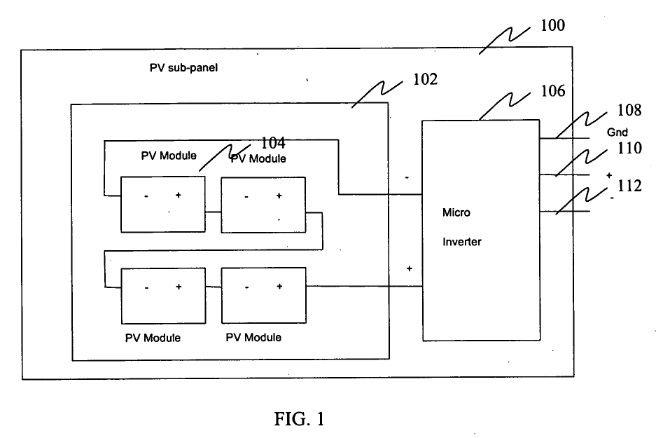

FIG. 1 illustrates an example of an integrated photovoltaic solar panel 100 including a solar sub-panel 102, one or more solar modules 104, a micro inverter 106, output electrical wires comprising a ground electrical wire 108, a positive (“+”) electrical wire 110 and a negative (“−”) electrical wire 112. Each photovoltaic solar module or PV module 104 comprises one or more solar cells and each solar cell is able to convert solar energy to DC electric power. In some embodiments, the solar modules 104 are connected with each other in series, i.e., the positive electrode of each solar module is connected with the negative electrode of another solar module through electrical wires. The connected solar modules are connected with the micro inverter 106 which receives DC electric power and converts the DC electric power to AC power. The micro inverter 106 outputs AC power through two or more electrical wires. In some embodiments, the micro inverter 106 comprises three output electrical wires—a ground electrical wire 108, a positive (“+”) electrical wire 110 and a negative (“−”) electrical wire 112. In some other embodiments, the micro inverter 106 comprises two output electrical wires—a positive (“+”) electrical wire 110 and a negative (“−”) electrical wire 112.

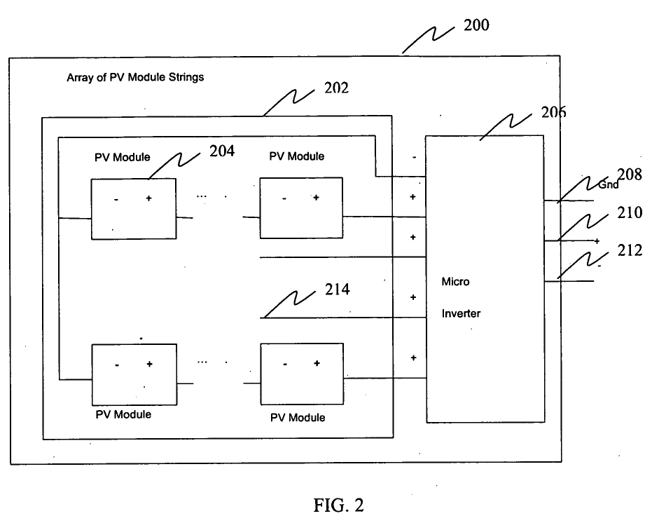

FIG. 2 illustrates another example of an integrated photovoltaic solar panel 200 comprising a sub-panel 202 which comprises one or more photovoltaic solar modules (PV modules) 204 that are connected in parallel to the micro inverter 206 through electrical wires 214. In some embodiments, one or more PV modules 204 may be connected in series and then connected to the micro inverter 206. In other embodiments, each PV module 204 is connected to the micro inverter 206 in parallel, i.e., each PV module is connected to the micro inverter 206 directly through electrical wires. The micro inverter 206 converts DC power received from the PV modules 204 and converts the DC power to AC power, and outputs the AC power through two or more electrical wires.

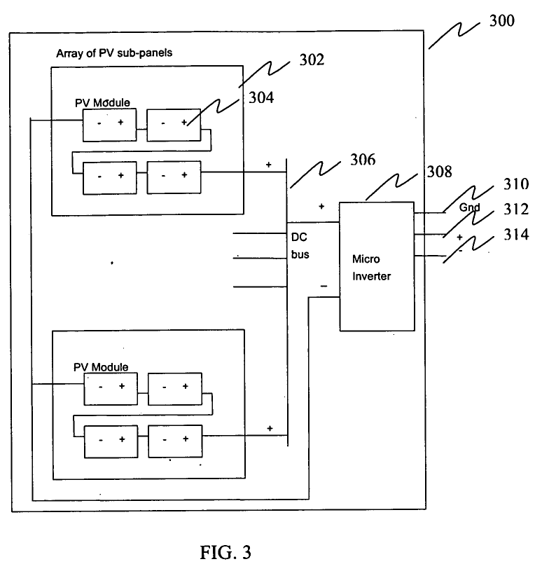

FIG. 3 illustrates yet another example of an integrated photovoltaic solar panel 300 comprising one or more sub-panels 302, a DC bus 306, and a micro inverter 308. Each sub-panel 302 comprises one or more PV modules 304. In some embodiments, the PV modules may be connected in series. One or more sub-panels 302 are connected to a DC bus 306 and a micro inverter 308. In some embodiments, the micro inverter 308 comprises three output electrical wires—a ground electrical wire 310, a positive (“+”) electrical wire 312 and a negative (“−”) electrical wire 314.

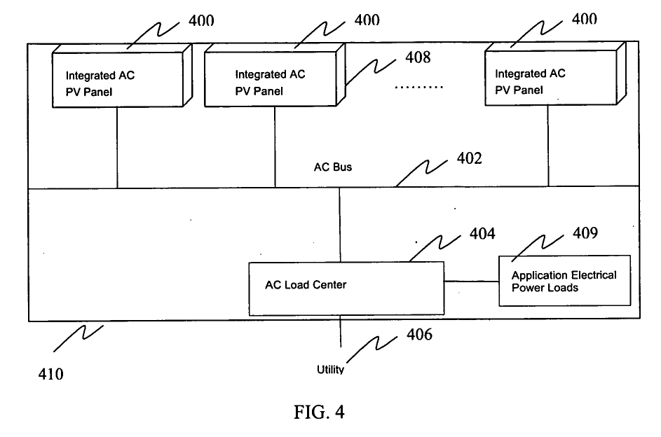

FIG. 4 illustrates, for didactic purposes, an integrated solar electric power generation system, which system may be used by an embodiment of the present invention. In the integrated solar electric power system 410, one or more integrated solar panels 400 are connected to an AC bus 402 which is coupled with an AC load center 404. In some embodiments, the integrated solar panels 400 may be mounted on a support frame 408. In some embodiments, support frame 408 may be made of aluminum, steel or other materials. The AC load center 404 is connected to a utility grid 406 and/or application electrical power loads 409.

As FIG. 4 illustrates, particular embodiments may operate on roof tops of a building, in a backyard or front yard, or on a balcony. For example, support frame 408 could be mounted on roof tops of a house, a commercial building, or any other building or structure. Support frame 408 may also be mounted on the outside wall of a building structure or on the ground of a backyard of a building. It may also be mounted on the balconies, or on the roof, of an apartment in an apartment building. In some embodiments, a power cable made of copper or other material may be used to safely carry the power generated by the solar electric system to an AC outlet socket. There is no need to modify any existing electrical service panels. The generated electric power is made compatible with existing electrical utility grid by the integrated solar electric power system.

Depending on the method of deployment, in some embodiments, a stand, a mounting bracket, or other mechanisms for securing the system may be needed. In other embodiments, the integrated solar panel may be mounted on a system that tracks the movement of the Sun to maximize sunlight exposure and increase the amount of power that can be generated.

In some embodiment, the integrated solar electric power generation system may be used as a household backup generator. Just like any household backup generator, once plugged into an existing electric socket, the entire house will have electricity provided by the system in parallel with the utility supply. In other embodiments, excess power may be sent back through the same circuitry that electrical power is sent to the house. Through the Sine Wave Generator included in the micro inverter of the integrated solar electric power system, as described below, the micro power input requirements of household appliances and power loads. The inverter design needs to comply with applicable regulatory codes. For example, there is the UL Standard 1703 on Inverters, Converters, and Controllers for Independent Power System. To be able to sell excess power generated back to the utility company, the output of the micro inverter needs to be conditioned so that it is also compatible with the electrical grid requirement. For example, in the U.S., the output of the inverter must conform to the IEEE Standard 929-2000, Recommended Practice for Utility Interface of Photovoltaic (PV) system.

Micro inverter 600 comprises four primary functional units: the DC power input isolation and on-off control unit 604, the Maximum Power Point Tracking unit 608, the DC-to-AC power transformation unit 610, and the Sine Wave Generator unit 612.

In one embodiment, the DC input Power Isolation and on-off control unit 604 comprises one or more inputs which come from the solar modules. Each string is isolated from others by the series diodes 604. This function also contains built-in electronic FET (Field Effect Transistor) switches 606 that are either closed to allow the passage of power or opened to deny the passage of power, depending on the status of the solar modules. In some embodiments, the input voltage from each string of solar modules ranges from 12-volt to 24.5-volt. The switch 606 is in the closed position when the voltage from the associated solar string is within this range. To protect the system from over-voltage or under-voltage, the switch 606 is in the opened position when the input voltage from its associated solar module string is outside the 12-volt to 24.5-volt range.

The Maximum Power Point Tracker (MPPT) unit 608 performs the summation of peak voltage and peak current from all strings into a single peak DC power output with the voltage fixed at 24 volt. The DC power output is sent to the transformer 610. When the voltage from any string of solar module goes below 12 volts or above 24.5 volts, MPPT 608 sends a signal to the associated switch 606 to disconnect that string. MPPT 608 also stops sending the DC power output to the transformer during utility blackout and upon receiving a cut-off command 620 from the Sine Wave Generator 612.

Transformer 610 is connected to the MPPT 608 output by one or more electrical wires. The MPPT 608 output is regulated at 24 volt DC. Transformer 610 performs the function of transforming received DC power to AC power. Transformer 610 comprises three output electrical wires—a ground electrical wire 614, a positive (“+”) electrical wire 616 and a negative (“−”) electrical wire 618. In some embodiments, transformer 610 may comprise a filter to smooth out the AC voltage. In other embodiments, a common household three prong extension cord may be used to connect the electrical wires 614, 616, and 618 to a wall outlet. One of the inlets of the three prong extension cord may be connected to the ground electrical wire 614 and the other two inlets may be connected to the positive (“+”) electrical wire 616 and the negative (“−”) electrical wire 618. The three prong plug of the extension cord may be plugged into the wall outlet to supply the AC electrical power generated by the integrated solar electric power generation system.

Sine Wave Generator 612 sends switching signals to the power switches of the primary winding of the transformer 610 to create AC power output. In some embodiments, a microprocessor or controller inside the Sine Wave Generator 612 stores the sine wave algorithm that enables the output of the inverter to track the grid voltage and to minimize output ripples on the power line. To meet the IEEE 929-2000 requirement for grid-tie inverters, the AC output voltage is sensed and rectified back to the Sine Wave Generator 612 in order to track, copy, and regulate the AC power output from the transformer 610. When utility blackout condition is sensed, the Sine Wave Generator sends a command 620 to the MPPT 608 to stop sending DC power output to the transformer 610.

The present invention has been explained with reference to specific embodiments. For example, while embodiments of the present invention have been described with reference to specific material, hardware and/or software components, those skilled in the art will appreciate that different combinations of material, hardware and/or software components may also be used. Other embodiments will be evident to those of ordinary skill in the art. It is therefore not intended that the present invention be limited, except as indicated by the appended claims.

What is claimed is:

1. An integrated solar array system comprising
one or more photovoltaic solar panels each having one or more photovoltaic solar modules, wherein each solar module is operative to convert solar light energy into DC electric power, and one or more micro inverters, wherein each micro inverter is operative to receive DC electric power and convert DC electric power to AC electric power;
one or more AC buses to which the one or more solar panels are connected;
an AC load center through which the one or more AC buses are connected to provide a power source;
a frame, on which the solar panel is mounted.

2. The system of claim 1, wherein each solar module comprises one or more solar cells operative to generate DC electric power and one or more electrical wires connected to the one or more micro inverters.

3. The system of claim 1, wherein each micro inverter comprises a DC electrical power isolation unit, a maximum power point tracker, a transformer, and a sine wave generator.

4. The system of claim 1, wherein the AC buses are connected to a utility power grid through two or more electrical wires.

5. The system of claim 1, wherein the AC buses are connected to application electrical power loads through two or more electrical wires.

6. The system of claim 1, wherein the utility power grid comprises a public utility power grid.

7. The system of claim 1, wherein the utility power grid comprises an enterprise utility power grid.

8. The system of claim 1, wherein the power source comprises a primary power source.

9. The system of claim 1, wherein the power source comprises a supplementary power source.

10. A method of providing an integrated alternating current photovoltaic solar panel comprising:
connecting one or more photovoltaic solar modules as one or more sub-panels, wherein each solar module is operative to convert solar light energy into DC electric power;
interconnecting the one or more sub-panels to a micro inverter wherein the micro inverter is operative to receive the DC electric power and convert the DC electric power to AC electric power;
outputting the AC electric power through two or more electrical wires.

11. The method of claim 10, wherein the interconnecting step further comprising linking the one or more sub-panels in series with the micro inverter.

12. The method of claim 10, wherein interconnecting step further comprising linking the one or more sub-panels in parallel with the micro inverter.

13. The method of claim 10, wherein each solar module comprises one or more solar cells operative to generate DC electric power and one or more electrical wires connected to the one or more micro inverters.

14. The method of claim 10, wherein each micro inverter comprises a DC electrical power isolation unit, a maximum power point tracker, a transformer, and a sine wave generator.

15. The method of claim 10, wherein interconnecting step further comprising linking the one or more sub-panels to a DC bus and linking the DC bus with the micro inverter.

16. An integrated solar array system comprising
one or more photovoltaic solar panels each having one or more photovoltaic solar modules, wherein each solar module is operative to convert solar light energy into DC electric power, and one or more micro inverters, wherein each micro inverter is operative to receive DC electric power and convert DC electric power to AC electric power;
one or more local AC buses to which the one or more solar panels are connected;
a main AC bus wherein the one or more local AC buses are connected to;
an AC load center through which the main AC bus is connect to provide a power source;
a frame, on which the integrated solar panel is mounted.

17. The integrated solar array system of claim 16 wherein the power source is a primary power source.

18. The integrated solar array system of claim 16 wherein the power source is a supplementary power source.

19. The integrated solar array system of claim 16 wherein the AC load center is connected to a public utility power grid.

20. The integrated solar array system of claim 16 wherein the AC load center is connected to application electrical power loads.
